(19) United States
(12) Patent Application Publication
(10) Pub. No.: US 2025/0274136 A1
(43) Pub. Date: Aug. 28, 2025

(54) SINGLE-INPUT DUAL-OUTPUT ANALOG-TO-DIGITAL CONVERTER

(71) Applicant: Qorvo US, Inc., Greensboro, NC (US)

(72) Inventors: Nadim Khlat, Cugnaux (FR); Christopher Truong Ngo, Queen Creek, AZ (US)

(21) Appl. No.: 19/036,160

(22) Filed: Jan. 24, 2025

Related U.S. Application Data
(60) Provisional application No. 63/557,675, filed on Feb. 26, 2024.

(51) Int. Cl. H03M 1/18; G01R 19/165; G01R 19/25; H03M 1/34

(52) U.S. Cl. CPC H03M 1/186; G01R 19/16576; G01R 19/25; H03M 1/34

(57) ABSTRACT

A single-input dual-output (SIDO) analog-to-digital converter (ADC) is disclosed. Herein, the SIDO ADC is configured to receive an analog input voltage and concurrently output a digital average and a digital peak of the received analog input voltage. Moreover, the SIDO ADC can be configured with a configurable dynamic range to output the digital average and the digital peak with sufficient granularity when the analog input voltage is associated with a larger peak-to-average ratio (PAR). As such, the SIDO ADC can effectively overcome the limitations in an existing single-input single-output (SISO) ADC.

### RELATED APPLICATIONS

This application claims the benefit of U.S. provisional patent application Ser. No. 63/557,675, filed on Feb. 26, 2024, the disclosure of which is hereby incorporated herein by reference in its entirety.

### FIELD OF THE DISCLOSURE

The technology of the disclosure relates generally to a single-input dual-output (SIDO) analog-to-digital converter (ADC) that can convert concurrently an analog input signal into a digital average signal and a digital peak signal.

### BACKGROUND

Mobile communication devices have become increasingly common in current society. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by wireless communication technologies, such as long-term evolution (LTE) and fifth-generation new radio (5G-NR). To achieve the higher data rates in mobile communication devices, sophisticated power amplifiers (PAs) may be employed to increase output power of radio frequency (RF) signals (e.g., maintaining sufficient energy per bit) communicated by mobile communication devices. However, the increased output power of RF signals can lead to increased power consumption and thermal dissipation in mobile communication devices, thus compromising overall performance and user experiences.

Notably, a mobile communication device often includes many analog-to-digital converters (ADCs) to convert analog signals into digital signals. FIG. 1 is a schematic diagram of an exemplary single-input single-output (SISO) ADC 10 that can convert an analog voltage V_{A} into a digital average voltage V_{AVG}. For an in-depth description as to how the existing SISO ADC 10 can convert the analog voltage V_{A} to the digital average voltage V_{AVG}, please refer to U.S. Pat. No. 11,268,990 B2, entitled “CURRENT MEASUREMENT CIRCUIT FOR OPTIMIZATION OF POWER CONSUMPTION IN ELECTRONIC DEVICES.”

The existing SISO ADC 10 may have certain limitations. In one aspect, the existing SISO ADC 10 may have a limited dynamic range that may cause the digital average voltage V_{AVG} to have a lower granularity when the analog voltage V_{A} is associated with a large peak-to-average ratio (PAR). In another aspect, although the existing SISO ADC 10 can produce the digital average voltage V_{AVG}, the existing SISO ADC 10 is unable to capture a digital peak of the analog voltage V_{A}. As such, it is desirable to optimize the existing SISO ADC 10 to overcome the above-mentioned limitations.

### SUMMARY

Embodiments of the disclosure relate to a single-input dual-output (SIDO) analog-to-digital converter (ADC). Herein, the SIDO ADC is configured to receive an analog input voltage and concurrently output a digital average and a digital peak of the received analog input voltage. Moreover, the SIDO ADC can be configured with a configurable dynamic range to output the digital average and the digital peak with sufficient granularity when the analog input voltage is associated with a larger peak-to-average ratio (PAR). As such, the SIDO ADC can effectively overcome the limitations in an existing single-input single-output (SISO) ADC.

In one aspect, a SIDO ADC is provided. The SIDO ADC includes a scaling circuit. The scaling circuit is configured to receive an analog input voltage and scale the analog input voltage down to a sense voltage. The SIDO ADC also includes a digital average voltage circuit. The digital average voltage circuit is configured to store a baseline voltage and multiple threshold voltages each higher than the baseline voltage to thereby establish multiple threshold regions. The digital average voltage circuit is also configured to count each occurrence of the sense voltage being higher than or equal to a highest one of the plurality of threshold voltages that falls below the sense voltage during a predefined measurement period in a corresponding one of multiple first counters. The digital average voltage circuit is also configured to reduce the sense voltage by a respective one of multiple offset values corresponding to the highest one of the plurality of threshold voltages that falls below the sense voltage. The digital average voltage circuit is also configured to output a digital average value indicating an average of the analog input voltage during the predefined measurement period based on a respective value in each of the multiple first counters. The SIDO ADC also includes a digital peak voltage circuit. The digital peak voltage circuit is configured to count a respective duration of the sense voltage staying within each of the multiple threshold regions during the predefined measurement period in multiple second counters. The digital peak voltage circuit is also configured to output a digital peak value indicating a peak of the analog input voltage during the predefined measurement period based on a respective value in each of the multiple first counters and each of the multiple second counters.

In another aspect, a method for converting an analog input voltage into a digital average value and a digital peak value is provided. The method includes receiving the analog input voltage and scaling the analog input voltage down to a sense voltage. The method also includes storing a baseline voltage and multiple threshold voltages each higher than the baseline voltage to thereby establish multiple threshold regions. The method also includes counting each occurrence of the sense voltage being higher than or equal to a highest one of the plurality of threshold voltages that falls below the sense voltage during a predefined measurement period in a corresponding one of multiple first counters. The method also includes reducing the sense voltage by a respective one of multiple offset values corresponding to the highest one of the plurality of threshold voltages that falls below the sense voltage. The method also includes outputting the digital average value indicating an average of the analog input voltage during the predefined measurement period based on a respective value in each of the multiple first counters. The method also includes counting a respective duration of the sense voltage staying within each of the multiple threshold regions during the predefined measurement period in multiple second counters. The method also includes outputting the digital peak value indicating a peak of the analog input voltage during the predefined measurement period based on a respective value in each of the multiple first counters and each of the multiple second counters.

In another aspect, a wireless device is provided. The wireless device includes at least one SIDO ADC. The at least one SIDO ADC includes a scaling circuit. The scaling circuit is configured to receive an analog input voltage and scale the analog input voltage down to a sense voltage. The at least one SIDO ADC also includes a digital average voltage circuit. The digital average voltage circuit is configured to store a baseline voltage and multiple threshold voltages each higher than the baseline voltage to thereby establish multiple threshold regions. The digital average voltage circuit is also configured to count each occurrence of the sense voltage being higher than or equal to a highest one of the plurality of threshold voltages that falls below the sense voltage during a predefined measurement period in a corresponding one of multiple first counters. The digital average voltage circuit is also configured to reduce the sense voltage by a respective one of multiple offset values corresponding to the highest one of the plurality of threshold voltages that falls below the sense voltage. The digital average voltage circuit is also configured to output a digital average value indicating an average of the analog input voltage during the predefined measurement period based on a respective value in each of the multiple first counters. The at least one SIDO ADC also includes a digital peak voltage circuit. The digital peak voltage circuit is configured to count a respective duration of the sense voltage staying within each of the multiple threshold regions during the predefined measurement period in multiple second counters. The digital peak voltage circuit is also configured to output a digital peak value indicating a peak of the analog input voltage during the predefined measurement period based on a respective value in each of the multiple first counters and each of the multiple second counters.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an existing single-input single-output (SISO) analog-to-digital converter (ADC) having some specific limitations;

FIG. 2 is a schematic diagram of an exemplary single-input dual-output (SIDO) ADC configured to output a digital average and a digital peak of an analog input voltage;

FIG. 3 is a schematic diagram providing an exemplary illustration of the SIDO ADC of FIG. 2 configured according to an embodiment of the present disclosure to output the digital average and the digital peak of the analog input voltage;

FIG. 4 is a graphic diagram providing an exemplary graphical illustration of multiple threshold voltages and multiple threshold regions whereby the SIDO ADC of FIG. 3 can output the digital average and the digital peak of the analog input voltage;

FIG. 5 is a graphic diagram illustrating a working example of the SISO ADC of FIG. 3;

FIG. 6 is a schematic diagram of an exemplary user element wherein the SIDO ADC of FIG. 2 can be provided; and

FIG. 7 is a flowchart of an exemplary process whereby the SIDO ADC of FIG. 2 can output the digital average and the digital peak of the analog input voltage.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a single-input dual-output (SIDO) analog-to-digital converter (ADC). Herein, the SIDO ADC is configured to receive an analog input voltage and concurrently output a digital average and a digital peak of the received analog input voltage. Moreover, the SIDO ADC can be configured with a configurable dynamic range to output the digital average and the digital peak with sufficient granularity when the analog input voltage is associated with a larger peak-to-average ratio (PAR). As such, the SIDO ADC can effectively overcome the limitations in an existing single-input single-output (SISO) ADC.

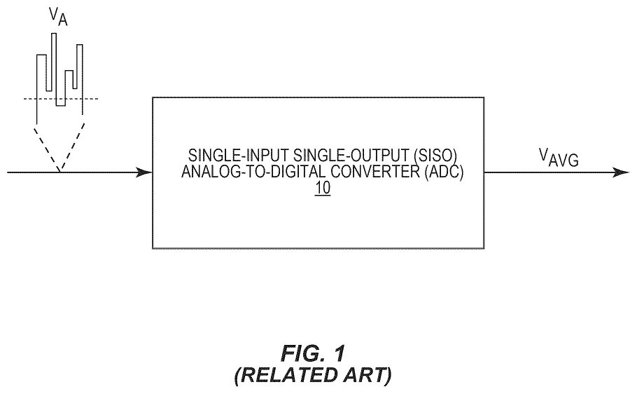

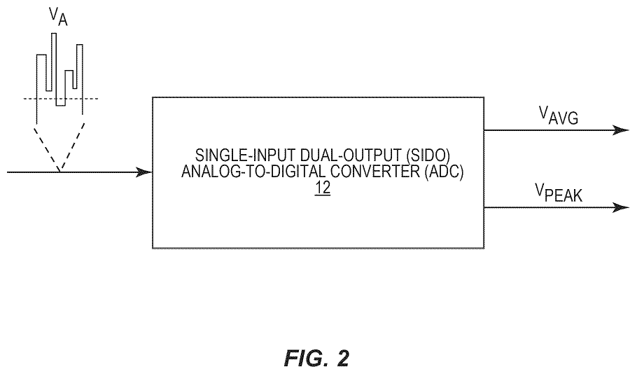

FIG. 2 is a schematic diagram of an exemplary SIDO ADC 12 configured to output a digital average V_{AVG} and a digital peak V_{PEAK} of an analog input voltage V_{A}. As described in detail below, the SIDO ADC 12 can be configured with a configurable dynamic range to output the digital average V_{AVG} and the digital peak V_{PEAK} with sufficient granularity, even when the analog input voltage V_{A} is associated with a larger PAR. As such, the SIDO ADC 12 can effectively overcome the limitations in the SISO ADC 10 of FIG. 1.

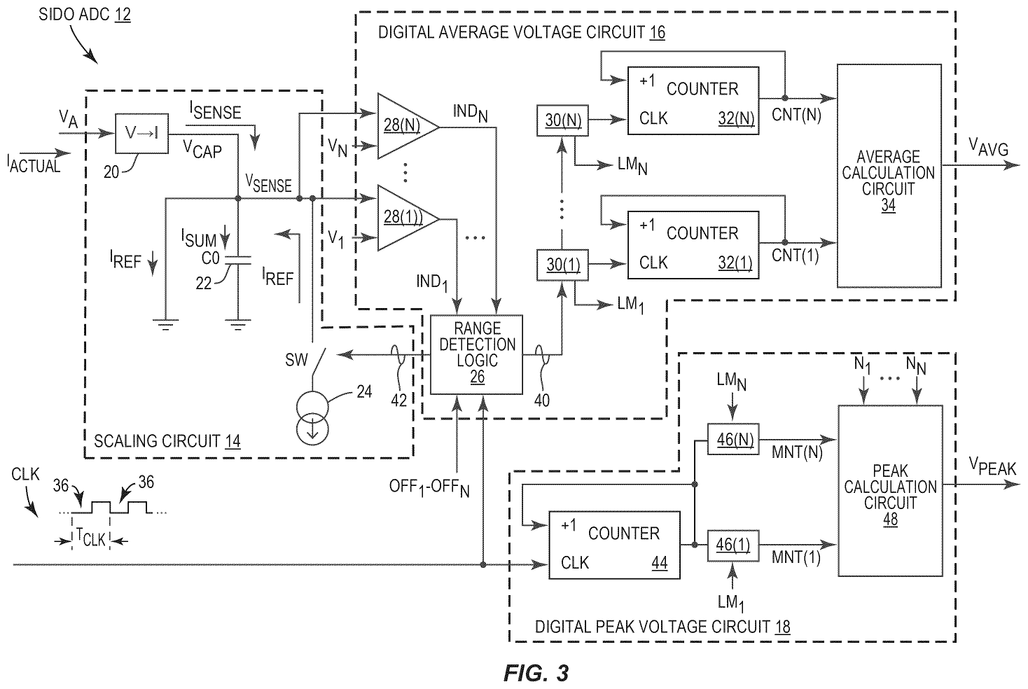

FIG. 3 is a schematic diagram of the SIDO ADC 12 of FIG. 2 configured according to an embodiment of the present disclosure. Common elements between FIGS. 2 and 3 are shown therein with common element numbers and will not be re-described herein.

Herein, the SIDO ADC 12 includes a scaling circuit 14, a digital average voltage circuit 16, and a digital peak voltage circuit 18. The scaling circuit 14 is configured to receive the analog input voltage V_{A}, which is associated with an electrical current I_{actual}, and scale down the analog input voltage V_{A} to a sense voltage Vₛₑₙₛₑ that is lower than the analog input voltage V_{A}. One benefit of scaling down the analog input voltage V_{A} is that the digital average voltage circuit 16 and the digital peak voltage circuit 18 will each operate with a lower voltage, thus allowing these circuits to be built with smaller electrical components (e.g., transistors, capacitors, etc.) to help reduce footprint and cost of the SIDO ADC 12.

In an embodiment, the scaling circuit 14 includes a voltage-to-current converter 20, a capacitor 22, and a reference current generator 24. The voltage-to-current converter 20 is configured to convert the analog input voltage V_{A} to a sense current Iₛₑₙₛₑ that is proportionally related to the electrical current I_{actual} as shown in equation (Eq. 1) below.

$${I}_{sense} = {I}_{actual} / {C}_{ratio} \qquad ( Eq . 1 )$$

In the equation (Eq. 1) above, Cᵣₐₜᵢₒ (Cᵣₐₜᵢₒ>1) represents a scaling factor (a.k.a. a ratio between the electrical current I_{actual} and the sense current Iₛₑₙₛₑ). The capacitor 22, which has a capacitance CO, is continuously charged by the sense current Iₛₑₙₛₑ to generate the sense voltage Vₛₑₙₛₑ. Understandably, since the sense current Iₛₑₙₛₑ is related to the electrical current I_{actual} by the scaling factor Cᵣₐₜᵢₒ, the sense voltage Vₛₑₙₛₑ is likewise related to the analog input voltage V_{A} by the scaling factor Cᵣₐₜᵢₒ. Thus, it is possible to convert the analog input voltage V_{A} into the digital average value V_{AVG} and the digital peak value V_{PEAK} based on the sense voltage Vₛₑₙₛₑ.

The reference current generator 24 may be coupled to or decoupled from the capacitor 22 by closing or opening a switch SW. When the reference current generator 24 is coupled to the capacitor 22, the reference current generator 24 will generate a reference current I_{ref} that flows in an opposite direction relative to the sense current Iₛₑₙₛₑ. In this regard, the reference current I_{ref} may be combined with the sense current Iₛₑₙₛₑ to generate a combined current Iₛᵤₘ (Iₛᵤₘ=Iₛₑₙₛₑ−I_{ref}). Since the reference current I_{ref} flows in the opposite direction relative to the sense current Iₛₑₙₛₑ, the reference current I_{ref} will offset (a.k.a. reduce) the sense current Iₛₑₙₛₑ that flows through the capacitor 22. As a result, the combined current Iₛᵤₘ may become smaller to thereby reduce the sense voltage Vₛₑₙₛₑ. Understandably, by generating the reference current I_{ref} at different levels, it is possible to reduce the sense voltage Vₛₑₙₛₑ by different offset values OFF₁-OFF_{N}. As further described below, the ability to reduce the sense voltage Vₛₑₙₛₑ by different offset values OFF₁-OFF_{N} allows the SIDO ADC 12 to have a configurable dynamic range and sufficient granularity when the analog input voltage V_{A} is associated with a larger PAR.

In an embodiment, the digital average voltage circuit 16 includes a range detection logic 26, multiple voltage comparators 28(1)-28(N), multiple first latches 30(1)-30(N), multiple first counters 32(1)-32(N) (e.g., flip-flop counters), and an average calculation circuit 34. Herein, there exists a one-to-one correspondence (a.k.a. association) between the voltage comparators 28(1)-28(N), the first latches 30(1)-30(N), and the first counters 32(1)-32(N). As an example, the voltage comparator 28(1) corresponds to the first latch 30(1) and the first counter 32(1), the voltage comparator 28(2) corresponds to the first latch 30(2) and the first counter 32(2), and so on. The range detection logic 26 and the first latches 30(1)-30(N) are each configured to operate based on a clock signal Clk, which corresponds to a number of clock cycles 36. Each of the clock cycles 36 has a respective clock duration T_{clk}.

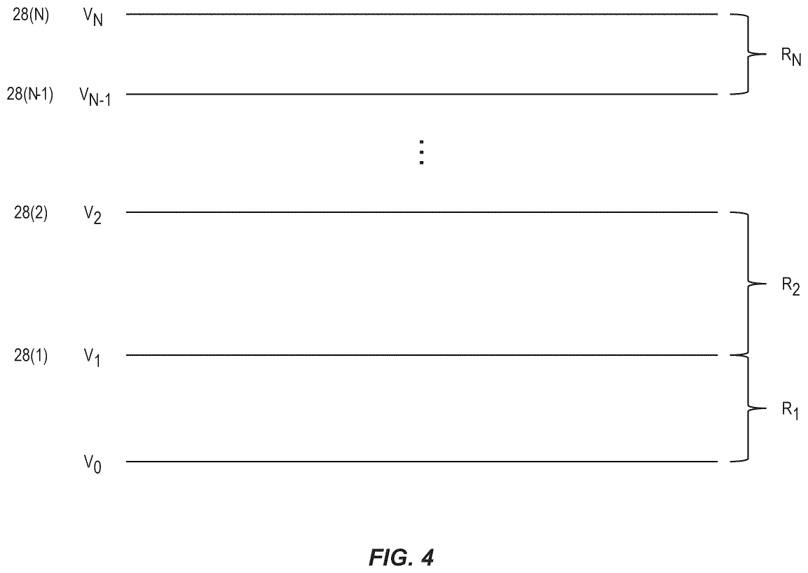

Each of the voltage comparators 28(1)-28(N) is configured to compare the sense voltage Vₛₑₙₛₑ with a respective one of multiple threshold voltages V₁-V_{N} to determine whether the sense voltage Vₛₑₙₛₑ is higher than or equal to the respective one of the threshold voltages V₁-V_{N}. In an embodiment, the threshold voltages V₁-V_{N} are different from one another and arranged in an ascending order (V₁<V₂< . . . <V_{N}). FIG. 4 provides an exemplary illustration of the threshold voltages V₁-V_{N} and their correspondence to the voltage comparators 28(1)-28(N).

Herein, V₀ represents a baseline voltage (a.k.a. initial voltage) of the sense voltage Vₛₑₙₛₑ and is lower than each of the threshold voltages V₁-V_{N} (V₀<V₁-V_{N}). The baseline voltage V₀ and the threshold voltage V₁ as well as each adjacent pair of the threshold voltages V₁-V_{N} can define a respective one of multiple threshold regions R₁-R_{N}. For example, the baseline voltage V₀ and the threshold voltage V₁ collectively define the threshold region R₁, the adjacent pair of the threshold voltages V₁ and V₂ collectively define the threshold region R2, and so on. Although the SIDO ADC 12 is indifferent to how the threshold regions R₁-R_{N} are defined, it may be preferable to have the threshold regions R₁-R_{N} equally spaced.

With reference back to FIG. 3, the threshold voltages V₁-V_{N} may be determined in accordance with the PAR of the analog input voltage V_{A} and/or a desired granularity in the digital average value V_{AVG} and the digital peak value V_{PEAK}. Thus, by determining the threshold voltages V₁-V_{N} properly, the SIDO ADC 12 can be configured to support a configurable dynamic range with desirable granularity. In one embodiment, the threshold voltages V₁-V_{N} may be configured statically (e.g., by preloading into onboard registers). In another embodiment, the threshold voltages V₁-V_{N} may be configured dynamically (e.g., via a radio frequency frontend (RFFE) interface).

Herein, each of the voltage comparators 28(1)-28(N) is further configured to output a respective threshold crossing indication INDᵢ (1≤i≤N) in response to determining that the sense voltage Vₛₑₙₛₑ is higher than or equal to the respective one of the threshold voltages V₁-V_{N}. Notably, not everyone of the voltage comparators 28(1)-28(N) will output the respective threshold crossing indication INDᵢ at a given time. For example, if the sense voltage Vₛₑₙₛₑ is higher than or equal to the threshold voltage V₂, then only the voltage comparators 28(1) and 28(2) will output the respective threshold crossing indication IND₁ and IND₂. Understandably, the voltage comparators 28(1)-28(N) will only output the respective threshold crossing indication INDᵢ simultaneously when the sense voltage Vₛₑₙₛₑ is higher than or equal to the threshold voltage V_{N}. In contrast, none of the voltage comparators 28(1)-28(N) will output the respective threshold crossing indication INDᵢ if the sense voltage Vₛₑₙₛₑ is below the threshold voltage V₁.

The range detection logic 26 is configured to determine which of the respective threshold crossing indications INDᵢ-IND_{N} is provided by a respective one of the voltage comparators 28(1)-28(N) corresponding to a highest one of the threshold voltages V₁-V_{N} that has been crossed by the sense voltage Vₛₑₙₛₑ. For example, if both the voltage comparators 28(1) and 28(2) output the respective threshold crossing indication IND₁ and IND₂, then the range detection logic 26 will determine that the respective threshold crossing indication IND₂ is associated with the highest threshold voltage V₂ among the threshold voltages V₁ and V₂ that have been crossed by the sense voltage Vₛₑₙₛₑ. Accordingly, the range detection logic 26 can provide a latch signal 40 to a corresponding one of the first latches 30(1)-30(N) to thereby cause a corresponding one of the first counters 32(1)-32(N) to increase by one (1). In the earlier example where the range detection logic 26 determines that the threshold voltage V₂ is the highest one among the threshold voltages V₁ and V₂, the range detection logic 26 will provide the latch signal 40 to the first latch 30(2) to thereby cause the first counter 32(2) to increase by 1.

Concurrent or subsequent to providing the latch signal 40, the range detection logic 26 further provides a control signal 42 to close the switch SW to thereby couple the reference current generator 24 to the capacitor 22. As described earlier, the reference current generator 24 will generate the reference current I_{ref} that flows in the opposite direction relative to the sense current Iₛₑₙₛₑ to reduce the sense current Iₛₑₙₛₑ and thereby the sense voltage Vₛₑₙₛₑ to below the highest one of the threshold voltages V₁-V_{N}. Referring to the above example once again, the range detection logic 26 will close the switch SW such that the sense voltage Vₛₑₙₛₑ can be reduced to below the threshold voltage V₂. Depending on the amount of the reference current I_{ref} being generated, the sense voltage Vₛₑₙₛₑ may even be reduced to below the threshold voltage V₁. In an embodiment, the amount of the reference current I_{ref} that the reference current generator 24 will generate can be defined by equation (Eq. 2) below.

$${I}_{ref} ( i ) = i * ( {N}_{max} * {I}_{unit} / {C}_{ratio} ) ( 1 \leq i \leq N ) \qquad ( Eq . 2 )$$

Herein, i represents an index of the threshold voltages V₁-V_{N} (1≤i≤N). I_{ref} (i) represents the reference current I_{ref} to be generated when the threshold voltage Vᵢ (1≤i≤N) among the threshold voltages V₁-V_{N} is determined to be the highest threshold voltage being crossed by the sense voltage Vₛₑₙₛₑ. Once again using the example described earlier, when the threshold voltage V₂ is determined to be the highest one of the threshold voltages V₁ and V₂ that was crossed by the sense voltage Vₛₑₙₛₑ, the reference current I_{ref}(2) will be equal to 2*(Nₘₐₓ*Iᵤₙᵢₜ/Cᵣₐₜᵢₒ) in accordance with the equation (Eq. 2).

In the equation (Eq. 2), Nₘₐₓ represents a maximum value that can be stored in an L-bit binary word, which is used to output the digital average value V_{AVG} and the digital peak value V_{PEAK}, respectively. For example, if the binary word is an 8-bit binary word (L=8), then the Nₘₐₓ would be equal to 256 (2⁸). In this regard, Nₘₐₓ also corresponds to a full-scale (maximum level) of the electrical current I_{actual} (hereinafter referred to as “MAX(I_{actual})”) that can be handled by the SIDO ADC 12. Accordingly, it is possible to divide the full-scale electrical current I_{actual} into a number of bitwise units Iᵤₙᵢₜ based on equation (Eq. 3) below.

$${I}_{unit} = MAX ( {I}_{actual} ) / {N}_{max} = MAX ( {I}_{actual} ) / {2}^{L} \qquad ( Eq . 3 )$$

The digital average voltage circuit 16 will repeat the procedures described above until an end of a predefined measurement period Tₘₑₐₛᵤᵣₑ (not shown). In a non-limiting example, the predefined measurement period Tₘₑₐₛᵤᵣₑ can be determined by equation (Eq. 4) below.

$${T}_{measure} = {N}_{max} * {T}_{clk} = {2}^{L} * {T}_{clk} \qquad ( Eq . 4 )$$

At the end of the predefined measurement period Tₘₑₐₛᵤᵣₑ, the average calculation circuit 34 will calculate a weighted average of the respective value stored in each of the first counters 32(1)-32(N) to thereby determine the digital average value V_{AVG}. In an embodiment, the average calculation circuit 34 can determine the digital average value V_{AVG} based on equation (Eq. 5) below.

$${V}_{AVG} = {\sum }_{i = 1}^{N} i * CNT ( i ) \qquad ( Eq . 5 )$$

In the equation (Eq. 5), i represents an index number of the first counters 32(1)-32(N) (1≤i≤N) and CNT (i) represents the respective value stored in a respective one of the first counters 32(1)-32(N). In this regard, the weighting factor for determining the digital average value V_{AVG} is equal to the index number of the first counters 32(1)-32(N).

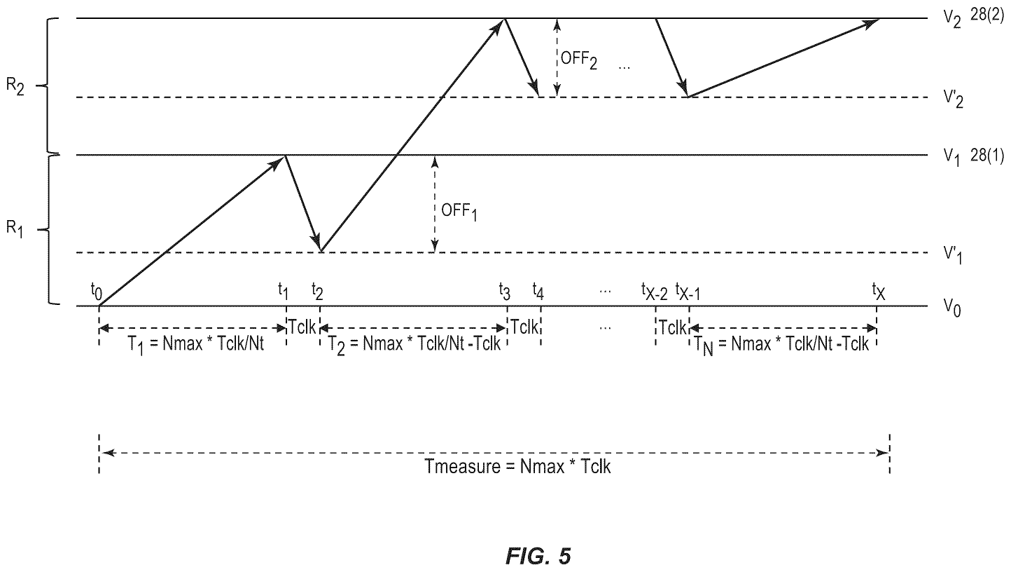

FIG. 5 is a graphic diagram illustrating a working example of the SIDO ADC 12 of FIG. 3 in determining the digital average value V_{AVG}. Common elements between FIGS. 3, 4, and 5 are shown therein with common element numbers and will not be re-described herein. For the sake of illustration, FIG. 5 illustrates a scenario wherein the SIDO ADC 12 of FIG. 3 is configured to operate with the baseline voltage V₀ and two threshold voltages V₁, V₂. It should be appreciated that the operating principles described herein can be applicable to any suitable number of the threshold voltages V₁-V_{N} as discussed in reference to FIG. 3.

At time to, which corresponds to a start of the predefined measurement period Tₘₑₐₛᵤᵣₑ, the sense voltage Vₛₑₙₛₑ is equal to the baseline voltage V₀. At time t₁, the capacitor 22 is charged by the sense current Iₛₑₙₛₑ to raise the sense voltage Vₛₑₙₛₑ to the first voltage threshold V₁. In a non-limiting example, the first voltage threshold V₁ can be determined based on equation (Eq. 6) below.

$${V}_{1} = {V}_{0} + ( {N}_{max} * {I}_{unit} * {T}_{clk} ) / ( C 0 * {C}_{ratio} ) \qquad ( Eq . 6 )$$

Accordingly, each of the threshold voltages V₁-V_{N} may be defined as a multiple of the first threshold voltage V₁, as in equation (Eq. 7) below.

$${V}_{i} = i * [ {V}_{0} + ( {N}_{max} * {I}_{unit} * {T}_{clk} ) / ( C 0 * {C}_{ratio} ) ] \qquad ( Eq . 7 )$$

In the equation (Eq. 7), i (1≤i≤N) represents the index number of the threshold voltages V₁-V_{N}. As the sense voltage Vₛₑₙₛₑ reaches the threshold voltage V₁, the first counter 32(1) is triggered by the first latch 30(1) to increase by 1. Concurrently or subsequently, the switch SW is closed to couple the reference current generator 24 to the capacitor 22 to generate the reference current I_{ref}. As discussed earlier, the reference current I_{ref} flows in the opposite direction relative to the sense current Iₛₑₙₛₑ to offset the sense current Iₛₑₙₛₑ. As a result, at time t₂, the sense voltage Vₛₑₙₛₑ may be reduced from the threshold voltage V₁ by the offset value OFF₁ to a reduced voltage level V′₁ (V₀<V′₁<V₁). In a non-limiting example, the duration between time t₁ and t₂ can equal the respective clock cycle duration Talk of each of the clock cycles 36.

At time t₂, the switch SW is opened to remove the reference current I_{ref}. As a result, the sense voltage Vₛₑₙₛₑ may start rising once again. For example, at time t₃, the sense voltage Vₛₑₙₛₑ may have climbed to the higher threshold voltage V₂. Accordingly, the first counter 32(2) will be triggered by the first latch 30(2) to increase by 1. Once again, the switch SW is closed to couple the reference current generator 24 to the capacitor 22 to generate the reference current I_{ref} to reduce the sense current Iₛₑₙₛₑ and, accordingly, the sense voltage Vₛₑₙₛₑ. As a result, at time t4, the sense voltage Vₛₑₙₛₑ may be reduced from the threshold voltage V₂ by the respective offset value OFF₂ to a reduced voltage level V′₂ (V₁<V′₂<V₂).

In this regard, the sense voltage Vₛₑₙₛₑ will increase and decrease during the predefined measurement period Tₘₑₐₛᵤᵣₑ in a zig-zag fashion and each of the first counters 32(1)-32(N) is configured to count each occurrence of the sense voltage Vₛₑₙₛₑ reaching a respective one of the threshold voltages V₁-V_{N}. At the end of the predefined measurement period (e.g., at time tₓ), the average calculation circuit 34 can calculate the digital average value V_{AVG} in accordance with the equation (Eq. 5).

With reference back to FIG. 3, the digital peak voltage circuit 18 is configured to output the digital peak value V_{PEAK}, concurrent to the digital average voltage circuit 16 outputting the digital average value V_{AVG}. In this regard, the digital peak voltage circuit 18 can be configured to include a clock counter 44, multiple second counters 46(1)-46(N), and a peak calculation circuit 48. Like the range detection logic 26 and the first latches 30(1)-30(N), the clock counter 44 is also configured to operate based on the clock signal Clk.

Herein, each of the second counters 46(1)-46(N) is configured to operate synchronously with a respective one of the first latches 30(1)-30(N). Specifically, each of the first latches 30(1)-30(N) is configured to generate a respective one of multiple latch signals LM₁-LM_{N} in response to receiving the latch signal 40 to latch a respective one of the second counters 46(1)-46(N). Together, the second counters 46(1)-46(N) will record a respective duration of the sense voltage Vₛₑₙₛₑ staying in each of the threshold regions R₁-R_{N} during the predefined measurement period Tₘₑₐₛᵤᵣₑ. At the end of the predefined measurement period Tₘₑₐₛᵤᵣₑ, the peak calculation circuit 48 will calculate the digital peak value V_{PEAK} based on a respective value in each of the second counters 46(1)-46(N). In an embodiment, the peak calculation circuit 48 may calculate the digital peak value V_{PEAK} based on equation (Eq. 8) below.

$${V}_{PEAK} = MAX [ i * CNT ( i ) / MNT ( i ) ] ( 1 \leq i \leq N ) \qquad ( Eq . 8 )$$

In the equation (Eq. 8), CNT (i) represents a respective value in each of the first counters 32(1)-32(N) and MNT (i) represents a respective value in each of the second counters 46(1)-46(N).

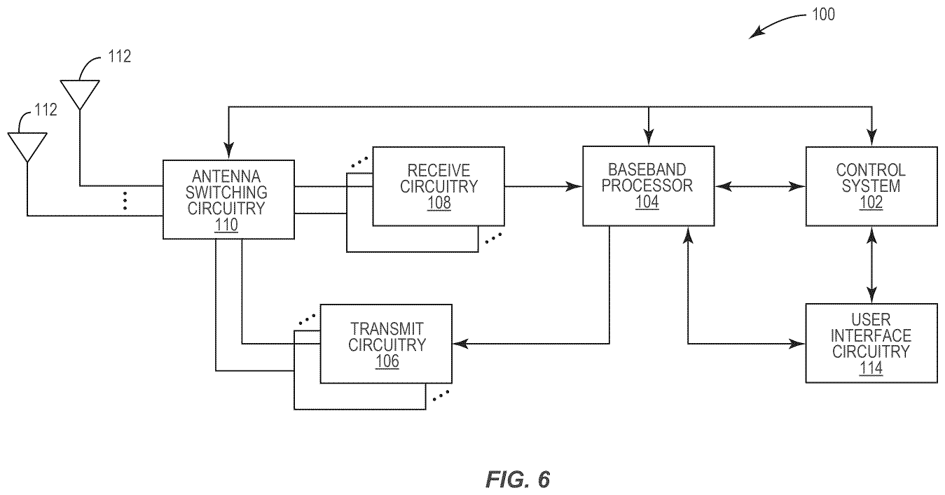

The SIDO ADC 12 of FIGS. 2 and 3 can be provided in a user element (e.g., a wireless device) to support the embodiments described above. In this regard, FIG. 6 is a schematic diagram of an exemplary user element 100 wherein the SIDO ADC 12 of FIGS. 2 and 3 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

The SIDO ADC 12 of FIG. 2 may be provided in any one or more of the circuitries in the user element 100, including but not limited to the control system 102, the baseband processor 104, the transmit circuitry 106, and the receive circuitry 108. It should be appreciated that the SIDO ADC 12 may also be provided in other types of electrical and/or electronic devices.

The SIDO ADC 12 of FIG. 2 may be operated based on a process.

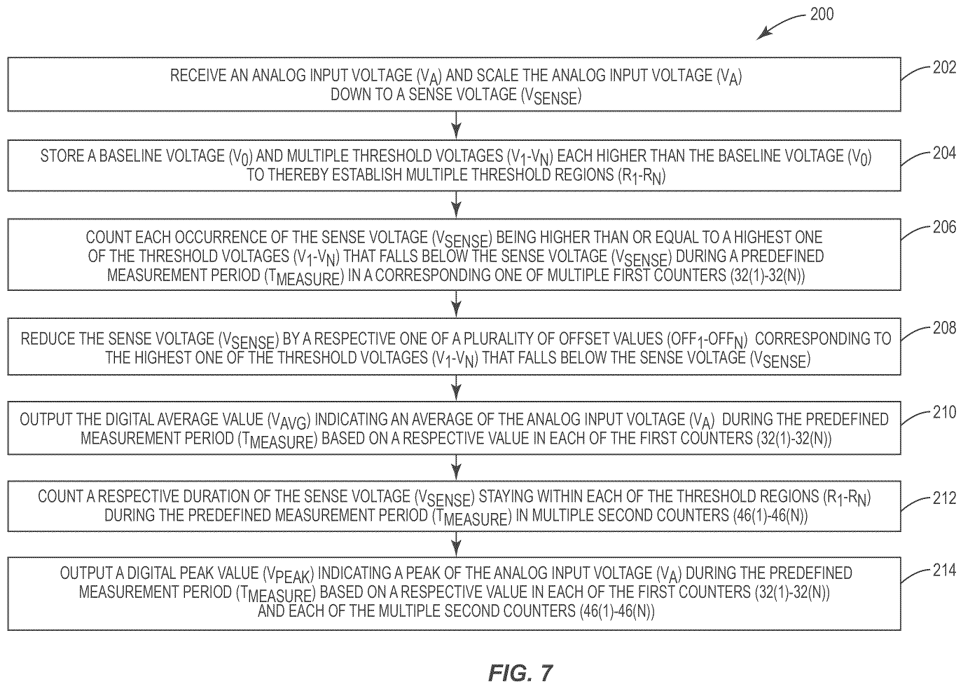

In this regard, FIG. 7 is a flowchart of an exemplary process 200 for operating the SIDO ADC 12 of FIG. 2.

Herein, the process 200 includes receiving the analog input voltage V_{A} and scaling the analog input voltage V_{A} down to the sense voltage Vₛₑₙₛₑ (step 202). The process 200 also includes storing the baseline voltage V₀ and the threshold voltages V₁-V_{N} each higher than the baseline voltage V₀ to thereby establish the threshold regions R₁-R_{N} (step 204). The process 200 also includes counting each occurrence of the sense voltage Vₛₑₙₛₑ being higher than or equal to a highest one of the threshold voltages V₁-V_{N} that falls below the sense voltage Vₛₑₙₛₑ during the predefined measurement period Tₘₑₐₛᵤᵣₑ in a corresponding one of the first counters 32(1)-32(N) (step 206). The process 200 also includes reducing the sense voltage Vₛₑₙₛₑ by a respective one of the offset values OFF₁-OFF_{N} corresponding to the highest one of the threshold voltages V₁-V_{N} that falls below the sense voltage Vₛₑₙₛₑ (step 208). The process 200 also includes outputting the digital average value V_{AVG} indicating the average of the analog input voltage V_{A} during the predefined measurement period Tₘₑₐₛᵤᵣₑ based on a respective value in each of the first counters 32(1)-32(N) (step 210). The process 200 also includes counting a respective duration of the sense voltage Vₛₑₙₛₑ staying within each of the threshold regions R₁-R_{N} during the predefined measurement period Tₘₑₐₛᵤᵣₑ in multiple second counters 46(1)-46(N) (step 212). The process 200 also includes outputting the digital peak value V_{PEAK} indicating a peak of the analog input voltage V_{A} during the predefined measurement period Tₘₑₐₛᵤᵣₑ based on a respective value in each of the first counters 32(1)-32(N) and each of the second counters 46(1)-46(N) (step 214).

Those skilled in the art will recognize improvements and modifications to the preferred embodiments of the present disclosure. All such improvements and modifications are considered within the scope of the concepts disclosed herein and the claims that follow.

What is claimed is:

1. A single-input dual-output (SIDO) analog-to-digital converter (ADC) comprising:
a scaling circuit configured to receive an analog input voltage and scale the analog input voltage down to a sense voltage;
a digital average voltage circuit configured to:
store a baseline voltage and a plurality of threshold voltages each higher than the baseline voltage to thereby establish a plurality of threshold regions;
count each occurrence of the sense voltage being higher than or equal to a highest one of the plurality of threshold voltages that falls below the sense voltage during a predefined measurement period in a corresponding one of a plurality of first counters;
reduce the sense voltage by a respective one of a plurality of offset values corresponding to the highest one of the plurality of threshold voltages that falls below the sense voltage; and
output a digital average value indicating an average of the analog input voltage during the predefined measurement period based on a respective value in each of the plurality of first counters; and
a digital peak voltage circuit configured to:
count a respective duration of the sense voltage staying within each of the plurality of threshold regions during the predefined measurement period in a plurality of second counters; and
output a digital peak value indicating a peak of the analog input voltage during the predefined measurement period based on a respective value in each of the plurality of first counters and each of the plurality of second counters.

2. The SIDO ADC of claim 1, wherein the scaling circuit comprises:
a voltage-to-current converter configured to convert the analog input voltage to a sense current based on a scaling factor that is less than one;
a capacitor configured to convert the sense current into the sense voltage; and
a reference current generator configured to generate a reference current to offset the sense current to thereby reduce the sense voltage by the respective one of the plurality of offset values.

3. The SIDO ADC of claim 2, wherein the reference current is proportionally increased in accordance with the plurality of threshold voltages.

4. The SIDO ADC of claim 1, wherein the digital average voltage circuit comprises:
a plurality of voltage comparators each configured to:
compare the sense voltage with a respective one of the plurality of threshold voltages to determine whether the sense voltage is higher than or equal to the respective one of the plurality of threshold voltages; and
output a respective threshold crossing indication in response to determining that the sense voltage is higher than or equal to the respective one of the plurality of threshold voltages;
a range detection logic configured to:
determine the respective threshold crossing indication provided by a respective one of the plurality of voltage comparators having the highest one of the plurality of threshold voltages that falls below the sense voltage;
cause a respective one of the plurality of first counters corresponding to the respective one of the plurality of voltage comparators to increase by one; and
cause the sense voltage to be reduced by the respective one of the plurality of offset values; and
an average calculation circuit configured to determine a weighted average of the respective value in each of the plurality of first counters to thereby output the digital average value.

5. The SIDO ADC of claim 4, wherein the average calculation circuit is further configured to determine the weighted average based on a plurality of weight factors that is increased in accordance with the plurality of threshold voltages.

6. The SIDO ADC of claim 1, wherein the digital peak voltage circuit comprises:
the plurality of second counters each latched with a respective one of the plurality of first counters to count the respective duration of the sense voltage staying within each of the plurality of threshold regions; and
a peak calculation circuit configured to determine the digital peak value based on a respective value in each of the plurality of second counters.

7. The SIDO ADC of claim 1, wherein each of the plurality of threshold regions corresponds to an identical voltage differential between each pair of adjacent threshold voltages among the plurality of threshold voltages.

8. A method for converting an analog input voltage into a digital average value and a digital peak value comprising:
receiving the analog input voltage and scaling the analog input voltage down to a sense voltage;
storing a baseline voltage and a plurality of threshold voltages each higher than the baseline voltage to thereby establish a plurality of threshold regions;
counting each occurrence of the sense voltage being higher than or equal to a highest one of the plurality of threshold voltages that falls below the sense voltage during a predefined measurement period in a corresponding one of a plurality of first counters;
reducing the sense voltage by a respective one of a plurality of offset values corresponding to the highest one of the plurality of threshold voltages that falls below the sense voltage;
outputting the digital average value indicating an average of the analog input voltage during the predefined measurement period based on a respective value in each of the plurality of first counters;
counting a respective duration of the sense voltage staying within each of the plurality of threshold regions during the predefined measurement period in a plurality of second counters; and
outputting the digital peak value indicating a peak of the analog input voltage during the predefined measurement period based on a respective value in each of the plurality of first counters and each of the plurality of second counters.

9. The method of claim 8, further comprising:
converting, using a voltage-to-current converter, the analog input voltage to a sense current based on a scaling factor that is less than one;
converting, using a capacitor, the sense current into the sense voltage; and
generating, using a reference current generator, a reference current to offset the sense current to thereby reduce the sense voltage by the respective one of the plurality of offset values.

10. The method of claim 9, further comprising increasing the reference current proportionally in accordance with the plurality of threshold voltages.

11. The method of claim 8, further comprising:
comparing, using each of a plurality of voltage comparators, the sense voltage with a respective one of the plurality of threshold voltages to determine whether the sense voltage is higher than or equal to the respective one of the plurality of threshold voltages;
outputting, from each of the plurality of voltage comparators, a respective threshold crossing indication in response to determining that the sense voltage is higher than or equal to the respective one of the plurality of threshold voltages;
determining, using a range detection logic, the respective threshold crossing indication provided by a respective one of the plurality of voltage comparators having the highest one of the plurality of threshold voltages that falls below the sense voltage;
causing, by the range detection logic, a respective one of the plurality of first counters corresponding to the respective one of the plurality of voltage comparators to increase by one;
causing, by the range detection logic, the sense voltage to be reduced by the respective one of the plurality of offset values; and
determining, using an average calculation circuit, a weighted average of the respective value in each of the plurality of first counters to thereby output the digital average value.

12. The method of claim 11, further comprising determining, using the average calculation circuit, the weighted average based on a plurality of weight factors that is increased in accordance with the plurality of threshold voltages.

13. The method of claim 8, further comprising:
latching each of the plurality of second counters with a respective one of the plurality of first counters to count the respective duration of the sense voltage staying within each of the plurality of threshold regions; and
determining, using a peak calculation circuit, the digital peak value based on a respective value in each of the plurality of second counters.

14. The method of claim 8, further comprising defining each of the plurality of threshold regions to correspond to an identical voltage differential between each pair of adjacent threshold voltages among the plurality of threshold voltages.

15. A wireless device comprising at least one single-input dual-output (SIDO) analog-to-digital converter (ADC), comprising:
a scaling circuit configured to receive an analog input voltage and scale the analog input voltage down to a sense voltage;
a digital average voltage circuit configured to:
store a baseline voltage and a plurality of threshold voltages each higher than the baseline voltage to thereby establish a plurality of threshold regions;
count each occurrence of the sense voltage being higher than or equal to a highest one of the plurality of threshold voltages that falls below the sense voltage during a predefined measurement period in a corresponding one of a plurality of first counters;
reduce the sense voltage by a respective one of a plurality of offset values corresponding to the highest one of the plurality of threshold voltages that falls below the sense voltage; and
output a digital average value indicating an average of the analog input voltage during the predefined measurement period based on a respective value in each of the plurality of first counters; and
a digital peak voltage circuit configured to:
count a respective duration of the sense voltage staying within each of the plurality of threshold regions during the predefined measurement period in a plurality of second counters; and
output a digital peak value indicating a peak of the analog input voltage during the predefined measurement period based on a respective value in each of the plurality of first counters and each of the plurality of second counters.

16. The wireless device of claim 15, wherein the at least one SIDO ADO is provided in one or more of a control system, a baseband processor, transmit circuitry, and receive circuitry in the wireless device.

17. The wireless device of claim 15, wherein the scaling circuit comprises:
a voltage-to-current converter configured to convert the analog input voltage to a sense current based on a scaling factor that is less than one;
a capacitor configured to convert the sense current into the sense voltage; and
a reference current generator configured to generate a reference current to offset the sense current to thereby reduce the sense voltage by the respective one of the plurality of offset values.

18. The wireless device of claim 15, wherein the digital average voltage circuit comprises:
a plurality of voltage comparators each configured to:
compare the sense voltage with a respective one of the plurality of threshold voltages to determine whether the sense voltage is higher than or equal to the respective one of the plurality of threshold voltages; and
output a respective threshold crossing indication in response to determining that the sense voltage is higher than or equal to the respective one of the plurality of threshold voltages;
a range detection logic configured to:
determine the respective threshold crossing indication provided by a respective one of the plurality of voltage comparators having the highest one of the plurality of threshold voltages that falls below the sense voltage;
cause a respective one of the plurality of first counters corresponding to the respective one of the plurality of voltage comparators to increase by one; and
cause the sense voltage to be reduced by the respective one of the plurality of offset values; and
an average calculation circuit configured to determine a weighted average of the respective value in each of the plurality of first counters to thereby output the digital average value.

19. The wireless device of claim 15, wherein the digital peak voltage circuit comprises:
the plurality of second counters each latched with a respective one of the plurality of first counters to count the respective duration of the sense voltage staying within each of the plurality of threshold regions; and
a peak calculation circuit configured to determine the digital peak value based on a respective value in each of the plurality of second counters.

20. The wireless device of claim 15, wherein each of the plurality of threshold regions corresponds to an identical voltage differential between each pair of adjacent threshold voltages among the plurality of threshold voltages.
